(19) United States
(12) Patent Application Publication
(10) Pub. No.: US 2026/0204946 A1
(43) Pub. Date: Jul. 16, 2026

(54) SYSTEMS, METHODS, AND APPARATUSES FOR SYNCHRONIZING ELECTRICAL METERS

(71) Applicant: Sense Labs, Inc., Cambridge, MA (US)

(72) Inventors: Hugh Emanuel Chung, Washington, DC (US); Matthew William Fishburn, Somerville, MA (US); Michael S. Phillips, Belmont, MA (US)

(21) Appl. No.: 19/396,102

(22) Filed: Nov. 20, 2025

Related U.S. Application Data
(63) Continuation of application No. PCT/US2025/011703, filed on Jan. 15, 2025.

(51) Int. Cl. H02J 13/13; G01R 22/06; H02J 3/0012

(52) U.S. Cl. CPC H02J 13/1331; G01R 22/063; G01R 22/068; H02J 3/0012

(57) ABSTRACT

A system for synchronizing electrical meters including a radio signal reference circuit, electrical meters, and a time alignment circuit. The radio signal reference circuit interprets a reference radio signal value including a description of a radio signal from a transmitter that electrically impinges on an electrical grid. Each of the electrical meters includes a sensor that interrogates an electrical property of an electrically coupled phase and generates an electrical signal in response to the electrical property. The time alignment circuit determines an expressed radio signal value for each of the electrical meters by processing the corresponding electrical signal to determine a time alignment metric in response to the reference radio signal value and the expressed radio signal value for each of the plurality of electrical meters, and determines a time synchronized electrical signal for each of the plurality of electrical meters in response to the time alignment metric.

### CROSS-REFERENCES TO RELATED APPLICATIONS

This application claims priority to and is a bypass continuation of International Patent Application Number PCT/US2025/011703, filed Jan. 15, 2025, and entitled “SYSTEMS, METHODS, AND APPARATUSES FOR SYNCHRONIZING ELECTRICAL METERS” (SAGE-0010-WO).

The foregoing application is incorporated herein by reference in its entirety for all purposes.

### BACKGROUND

Power companies maintain electrical grids for the generation of electrical power and the transmission of electrical power to end users, such as businesses and residential homes. The electrical grid may extend over long distances to provide electrical power to all the end users of the electrical company. Power events, e.g., cut power lines, malfunctioning transformers, etc., may occur at different points along the electrical grid and disrupt the transmission of electrical power to end users and/or create dangerous risks, such as the risk of a fire started by the electrical grid.

Power events may be reported by end users, such as a report that a tree fell on an electrical line. Power events may also be discovered by electrical company employees, such as employees who perform inspections of the electrical grid. An electrical company may, however, not receive timely notifications of some events, and the lack of timely notifications may cause deteriorated services (e.g., longer power outages) and increased risks, such as the risk of fire.

Moreover, traditional methods of localizing power events provide poor precision and accuracy, e.g., several miles of a true location, or rely on manual inspection of power lines to identify the location of an event with precision and/or accuracy sufficient to guide repair crews to the site of the event.

### SUMMARY

Disclosed herein are systems, methods, and apparatuses that provide for the ability to synchronize electrical meters, disposed at different location on an electrical grid, with a level of precision sufficient to guide repair crews to an event site, for example localize power events to within a few blocks, or in certain embodiments to a specific component that is likely to be involved with the event. In particular, and as will be disclosed in further detail herein, embodiments of the current disclosure utilize radio station signals to synchronize the output of electrical meters such that the outputs of all the electrical meters can be sampled up to and including 1 MHz and, in some embodiments, higher than 1 MHz.

For example, a non-limiting embodiment of the current disclosure includes a system for synchronizing a plurality of electrical meters. The system includes a radio signal reference circuit, the plurality of electrical meters, and a time alignment circuit. The radio signal reference circuit is structured to interpret a reference radio signal value that includes a description of a radio signal from a transmitter that electrically impinges on an electrical grid, the radio signal having a carrier frequency. The plurality of electrical meters are disposed at distinct locations and are each electrically coupled to a phase of a plurality of phases of an electrical grid. Each of the plurality of electrical meters includes a sensor structured to: interrogate an electrical property of the electrically coupled phase at a sampling rate, wherein the sampling rate is at least equal to the carrier frequency, and generate an electrical signal in response to the electrical property. The time alignment circuit is structured to: determine an expressed radio signal value for each of the plurality of electrical meters by processing the corresponding electrical signal to determine a time alignment metric in response to the reference radio signal value and the expressed radio signal value for each of the plurality of electrical meters, and determine a time synchronized electrical signal for each of the plurality of electrical meters in response to the time alignment metric. In embodiments, the system may further include a synchronization provisioning circuit structured to transmit the time synchronized electrical signal for each of the plurality of electrical meters.

Another embodiment of the current disclosure provides a method for synchronizing a plurality of electrical meters. The method includes interpreting, via a radio signal reference circuit, a reference radio signal value including a description of a radio signal from a transmitter that electrically impinges on an electrical grid, the radio signal having a carrier frequency. The method further includes, for each of a plurality of sensors, interrogating, via the sensor and at a sampling rate, an electrical property of one of a plurality of electrically coupled phases of an electrical grid. Each of the plurality of sensors forms part of one of a plurality of electrical meters disposed at distinct locations, each of the plurality of electrical meters is electrically coupled to one of the plurality of phases, and the sampling rate is at least equal to the carrier frequency. The method further includes, for each of the plurality of sensors, generating, via the sensor, an electrical signal in response to the electrical property; determining, via a time alignment circuit, an expressed radio signal value for each of the plurality of electrical meters by processing the corresponding electrical signal to determine a time alignment metric in response to the reference radio signal value and the expressed radio signal value for each of the plurality of electrical meters; and determining, via the time alignment circuit, a time synchronized electrical signal for each of the plurality of electrical meters in response to the time alignment metric. In embodiments, the method further includes transmitting, via a synchronization provisioning circuit, the time synchronized electrical signal.

Yet another embodiment of the current disclosure provides for an electrical meter for synchronizing a plurality of electrical meters. The electrical meter includes a sensor, a radio signal reference circuit, a meter signal processing circuit, and a time alignment circuit. The sensor is structured to interrogate an electrical property of an electrically coupled phase, of a plurality of phases of an electrical grid, at a sampling rate, wherein the sampling rate is at least equal to a carrier frequency of a radio signal from a transmitter that electrically impinges on the electrical grid. The sensor is further structured to generate an electrical signal in response to the electrical property. The radio signal reference circuit is structured to interpret a reference radio signal value including a description of the radio signal. The meter signal processing circuit structured to interpret a plurality of electrical signals, including the electrical signal, wherein each of the plurality of electrical signals is from a distinct one of a plurality of electrical meters disposed at distinct locations, wherein each of the plurality of electrical meters is electrically coupled to a phase of the plurality of phases of the electrical grid. The time alignment circuit is structured to determine an expressed radio signal value for each of the plurality of electrical meters by processing the corresponding electrical signal to determine a time alignment metric in response to the reference radio signal value and the expressed radio signal value for each of the plurality of electrical meters. The time alignment circuit is further structured to determine a time synchronized electrical signal for each of the plurality of electrical meters in response to the time alignment metric. In embodiments, the electrical meter further includes a synchronization provisioning circuit structured to transmit the time synchronized electrical signal for each of the plurality of electrical meters.

Yet another embodiment provides for another method for synchronizing a plurality of electrical meters. The method includes interrogating, via a sensor of an electrical meter, an electrical property of an electrically coupled phase, of a plurality of phases of an electrical grid, at a sampling rate, wherein the sampling rate is at least equal to a carrier frequency of a radio signal from a transmitter that electrically impinges on the electrical grid. The method further includes generating, via the sensor, an electrical signal in response to the electrical property; interpreting, via a radio signal reference circuit of the electrical meter, a reference radio signal value including a description of the radio signal; and interpreting, via a meter signal processing circuit, a plurality of electrical signals, including the electrical signal. Each of the plurality of electrical signals is from a distinct one of a plurality of electrical meters disposed at distinct locations, and each of the plurality of electrical meters is electrically coupled to a phase of the plurality of phases of the electrical grid. The method further includes determining, via a time alignment circuit, an expressed radio signal value for each of the plurality of electrical meters by processing the corresponding electrical signal to determine a time alignment metric in response to the reference radio signal value and the expressed radio signal value for each of the plurality of electrical meters. The method further includes determining, via the time alignment circuit, a time synchronized electrical signal for each of the plurality of electrical meters in response to the time alignment metric. In embodiments, the method further includes transmitting, via a synchronization provisioning circuit, the time synchronized electrical signal for each of the plurality of electrical meters.

Yet another embodiment of the current disclosure provides for another electrical meter for synchronizing a plurality of electrical meters. The electrical meter includes an antenna, a sensor, and a snapshot circuit. The antenna is structured to receive a radio signal from a transmitter. The sensor is structured to interrogate an electrical property of an electrically coupled phase, of a plurality of phases of an electrical grid, at a sampling rate, wherein the sampling rate is at least equal to a carrier frequency of the radio signal. The sensor is further structured to generate an electrical signal in response to the electrical property. The snapshot circuit is structured to generate snapshot data based at least in part on the radio signal and the electrical signal. In embodiments, the electrical meter may further include a snapshot provisioning circuit structured to transmit the snapshot data.

Yet another embodiment of the current disclosure provides for another method for synchronizing a plurality of electrical meters. The method includes: receiving, via an antenna of an electrical meter, a radio signal from a transmitter; and interrogating, via a sensor of the electrical meter, an electrical property of an electrically coupled phase, of a plurality of phases of an electrical grid, at a sampling rate, wherein the sampling rate is at least equal to a carrier frequency of the radio signal. The method further includes generating, via the sensor, an electrical signal in response to the electrical property; and generating, via a snapshot circuit of the electrical meter, snapshot data based at least in part on the radio signal and the electrical signal. In embodiments, the method further includes transmitting, via a snapshot provisioning circuit of the electrical meter, the snapshot data.

These and other systems, methods, objects, features, and advantages of the present disclosure will be apparent to those skilled in the art from the following detailed description of the preferred embodiment and the drawings.

All documents mentioned herein are hereby incorporated in their entirety by reference. References to items in the singular should be understood to include items in the plural, and vice versa, unless explicitly stated otherwise or clear from the text. Grammatical conjunctions are intended to express any and all disjunctive and conjunctive combinations of conjoined clauses, sentences, words, and the like, unless otherwise stated or clear from the context.

### BRIEF DESCRIPTION OF THE FIGURES

The disclosure and the following detailed description of certain embodiments thereof may be understood by reference to the following figures:

FIG. 1 is a schematic diagram of a system for synchronizing electrical meters, in accordance with embodiments of the current disclosure;

FIG. 2 is schematic diagram of a distribution station and main power lines for a residence, in accordance with embodiments of the current disclosure;

FIG. 3 is a schematic diagram of an apparatus for synchronizing electrical meters, in accordance with embodiments of the current disclosure;

FIG. 4 is a schematic diagram depicting further embodiments of the apparatus of FIG. 3, in accordance with embodiments of the current disclosure;

FIG. 5 is a flowchart depicting a method for synchronizing electrical meters, in accordance with embodiments of the current disclosure;

FIG. 6 is a flowchart depicting further aspects of the method of FIG. 5, in accordance with embodiments of the current disclosure;

FIG. 7 is schematic diagram of a meter for synchronizing electrical meters, in accordance with embodiments of the current disclosure;

FIG. 8 is a flowchart depicting another method for synchronizing electrical meters, in accordance with embodiments of the current disclosure;

FIG. 9 is a flowchart depicting further aspects of the method of FIG. 8, in accordance with embodiments of the current disclosure;

FIG. 10 is a chart depicting unsynchronized meter readings;

FIG. 11 is a chart depicting synchronized meter readings, in accordance with embodiments of the current disclosure;

FIGS. 12A-12E are charts depicting correlated expressed radio signal values, in accordance with embodiments of the current disclosure;

FIG. 13 is a chart depicting a fault in unsynchronized meter readings;

FIG. 14 is a chart depicting the fault of FIG. 13 in synchronized meter readings;

FIG. 15 is a chart depicting the synchronized meter readings of FIG. 14 overlayed on each other;

FIG. 16 is a chart depicting meter readings in unsynchronized and synchronized forms, in accordance with embodiments of the current disclosure;

FIG. 17 is a chart depicting expressed radio signal value delay between electrical meters, in accordance with embodiments of the current disclosure; and

FIG. 18 is a schematic diagram of a plurality of radio signals impinging on a plurality of electrical meters; in accordance with embodiments of the current disclosure.

### DETAILED DESCRIPTION

Embodiments of the current disclosure provide for the use of radio signals to sample electrical meter output data at 1 MHz or higher. As disclosed in further detail herein, a sampling resolution of 1 MHz or higher provides for the ability to synchronize the output data of a plurality of electrical meters disposed at different locations of an electrical grid. Embodiments of the current disclosure may provide for the synchronization of electrical meters (and/or other devices) within about less than-or-equal-to about 10 feet, 50 feet, 100 feet, 0.1 miles, 0.25 miles, 0.5 miles, 1 mile, 5 miles, 10 miles, 20 miles, 100 miles; and/or or between any two locations that receive the same radio signal.

As will be appreciated, and described in greater detail herein, embodiments use of AM radio waves provide for an improved time alignment metric (that provides for meter signal/readings/data alignment) using equipment that is, on average, less expensive and/or smaller in size than traditional GPS equipment. For example, some embodiments of the current disclosure do not require any dedicated equipment for receiving the radio signal (and/or other timing signals) to be disposed on and/or in the equipment used to sense the electrical grid, e.g., meters.

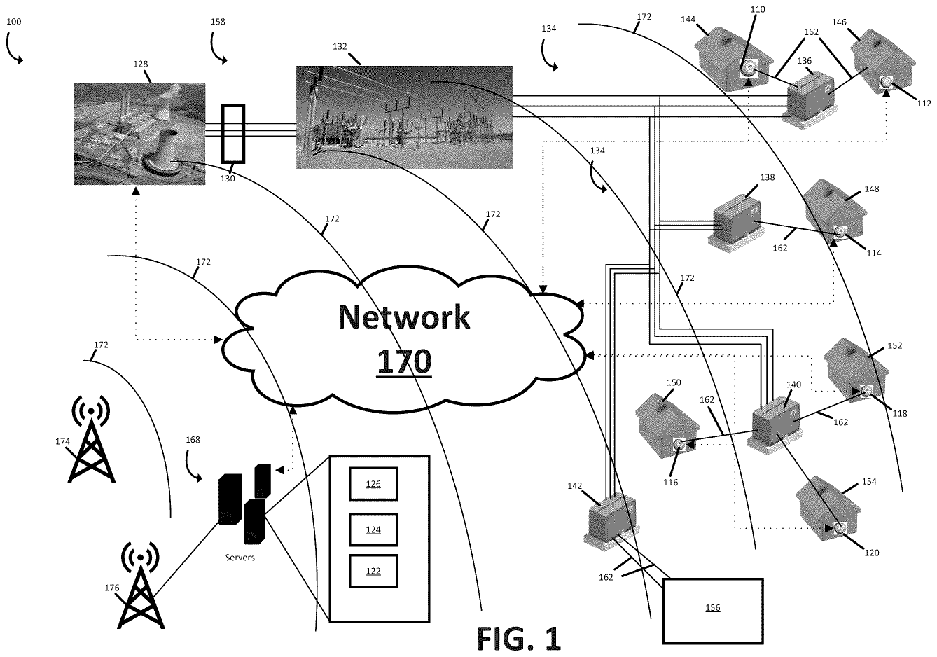

Referring to FIG. 1, a system 100 includes a radio signal reference circuit 122, a plurality of electrical meters 110, 112, 114, 116, 118, 120 (also referred to herein simple as meters), and a time alignment circuit 124. In embodiments, the system 100 may further include a synchronization provisioning circuit 126. As shown in FIG. 1, a power plant 128 generates electricity, also referred to herein as electrical power, which is then transmitted via high-voltage power lines 130 through one or more substations 132 where it may be stepped down to mid-and/or low-level power lines 134, where distribution stations 136, 138, 140, 142 which distribute electrical power to residences 144, 146, 148, 150, 152, 154 and/or businesses 156. As will be understood, the power plant 128, high voltage lines 130, substations 132, mid-low-level distribution lines 134, distribution stations 136, 138, 140, meters 110, 112, 114, 118, 116, 120, consuming devices (e.g., home appliances, commercial equipment, and/or industrial equipment) that consume electrical power generated by the power plant 128 collectively form an electrical grid 158. It is to be further understood that any device that electrically couples to the electrical grid 158 also forms part of the electrical grid 158.

The power plant 128 may employ any appropriate power generation technique, such as coal, natural gas, hydro, nuclear, wind, solar, and/or combinations thereof. While FIG. 1 depicts a single power plant 128, it is to be understood than an electrical grid 158 may include multiple power plants. The power plant 128 may generate alternating current (AC) or direct current (DC) electricity. AC electrical power may be generated at any suitable frequency, e.g., 50 Hz or 60 Hz and in any phase configuration, e.g., single (1) phase, double (2) phase, or three (3) phase, and delivered to consumers at any suitable voltage, e.g., 110 V or 230 V. While embodiments of the system 100 are discussed herein with respect to a 110V, 60 Hz 3-phase AC power grid 158, it will be understood that other types of electrical standards are contemplated, e.g., 230 V, 50 Hz, 3-phase AC power, and that the principles of the current disclosure are equally applicable. Accordingly, in embodiments, 3-phase AC electrical power generated by the power plant 128 may be conditioned, e.g., stepped up, to high voltage levels, e.g., 115,000-500,000 V, by a high-voltage transformer 160 for transmission along high-voltage lines 130 to the one or more substations 132.

The one or more substations 132 may step the electrical power down a medium voltage, e.g., 11,000-33,000 V, with additional transformers (not shown) stepping the power down further to 120-480 V which is delivered to distribution stations 136, 138, 140.

The distribution stations 136, 138, 140 may receive all three phases and couple a residence 114, 146, 148, 150, 152, 154 to one of the phases (represented by the single line connections in FIG. 1), and/or may couple a business/industrial facility 156 to two or more phases (represented by the double line connections between distribution station 142 and facility 156 in FIG. 1). Power lines coupling a distribution stations 36, 138, 140 to a consumer/end user 144, 146, 148, 150, 152, 154, 156 are referred to herein as electrical mains 162 or simply as mains.

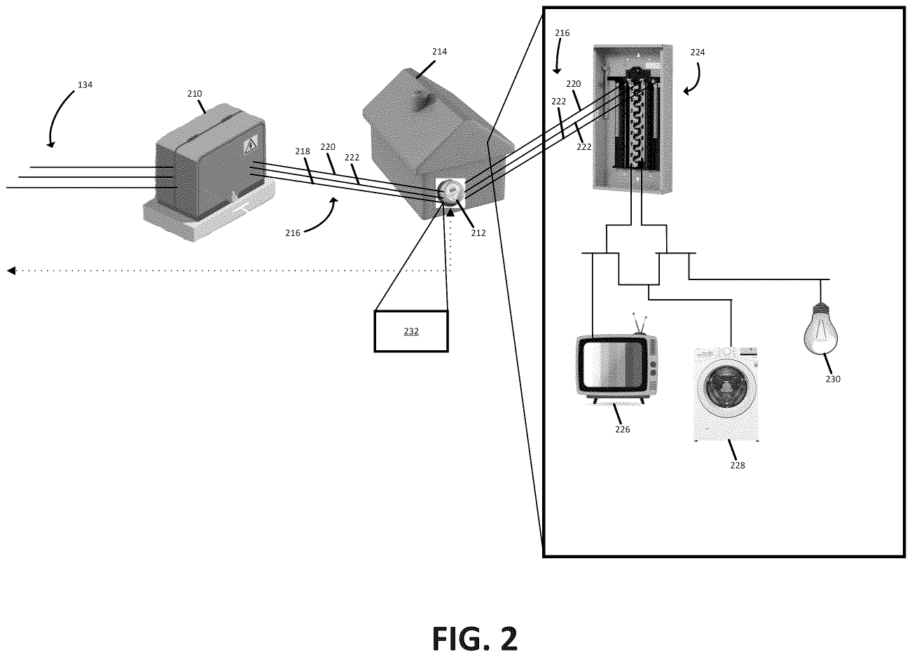

The electrical meters 110, 112, 114, 116, 118, 120 are disposed at consumers/end users 144, 146, 148, 150, 152, 154, 156 and are structured to monitor the amount of electrical power consumed by a consumer/end user 144, 146, 148, 150, 152, 154, 156. FIG. 2 depicts an example distribution station 210 (corresponding to 136, 138, 140 in FIG. 1), meter 212, and consumer 214. Electrical power flows to the distribution station 210 via medium to low level power lines 134, where it is stepped down and/or otherwise conditioned to arrive at the consumer 214 as 110V, 60 Hz single-phase AC electrical power via mains 216 (corresponding to 162 in FIG. 1). For example, the distribution station 210 may electrically couple the mains 216 to one of the 3-phases 134. Mains 216 are depicted in FIG. 2 as three wires to represent two mains 218 and 220 and a neutral 222. The mains 216 electrically couple to an electrical panel 224 (also referred to herein as a panel or main panel) which distributes the electrical power to consuming appliances, e.g., a TV 226, electric dryer 228 (shown as connected to both mains 218 and 220 to represent a 240 V connection), and/or lights 230.

Referring back to FIG. 1, the power plant 128 and/or meters 110, 112, 114, 116, 118, 120 may be connected to one or more servers 168 via a network 170. The network 170 may include the Internet and/or private networks and be TCP/IP based. The network may include land lines, e.g., copper lines, optical fibers, etc., and/or wireless connections, e.g., cellular communications, WiFi, Bluetooth, microwave transmissions, and/or the like. In embodiments, one or more of the high-voltage transformer, substations 132, distribution stations 136, 138, 140, 142, and/or any other device disclosed herein may be connected to any other device disclosed herein via the network 170. In embodiments, the meters 110, 112, 114, 116, 118, 120 sample/read/interrogate the electrical power on mains 216 via a sensor 232 (FIG. 2) and send readings back to the one or more servers 168. In embodiments, meter readings may include amperage, voltage, impedance, and/or any other type of electrical property of a power line. In embodiments, the sensor 232 may be an analogue-to-digital sensor (ADC). IN embodiments, the sensor 232 may be two ADCs, where a first ADC is structured to sense the electrical property and the second ADC is structured to sense the embedded radio signal. For example, in embodiments, the first ADC may have a sampling rate of 41.667 kHz, and the second ADC may have a sampling rate of 1 MHz. In embodiments, the second ADC may have a sampling rate suitable for sampling any of the carrier frequency ranges disclosed herein.

In embodiments of the system, a radio signal (represented by lines 172) may be broadcasted from a tower 174 such that the radio signal impinges on, couples with, and/or otherwise interacts with one or more components of the electrical grid 158, e.g., the power lines 130, 134, and 162. As such, the radio signal becomes embedded within the electrical power measured by the meters 110, 112, 114, 116, 118, and 120, and, as such, becomes embedded within the readings. As explained in greater detail herein, the embedded radio signal can be recovered and used to synchronize the readings from the meters 110, 112, 114, 116, 118, and 120.

For example, the radio signal 172 may have a carrier signal and a modulating signal, as is the case in AM radio, where the electrical meter sensors 232 (FIG. 2) are structured to interrogate one or more electrical properties of the electrically coupled phases at a sampling rate that, in embodiments, may be at least equal to the carrier frequency, and generate an electrical signal in response to the electrical property. It will be understood that the carrier signal may not be transmitted, and may alternatively be added locally at a component of the present system, for example by the radio signal reference circuit, and/or the carrier signal may be simulated in the frequency analysis and decomposition of the electrical signal (i.e., the carrier signal portion may be not present at all in certain embodiments and/or at certain operating conditions). Even where the radio signal 172 does not include a carrier signal, the carrier frequency is relevant as the modulating signal is modulating for a signal at the carrier frequency, and accordingly embodiments herein utilize and reference the carrier frequency for the radio signal 172. The electrical signal may be transmitted to the one or more servers 168 via the network 170 as a reading. In embodiments, the carrier frequency may be from about 275 kHz to about 1 MHz. In embodiments, the carrier frequency may be from about 275 kHz to about 1.5 MHz. In embodiments, the carrier frequency may be from about 275 kHz to about 1.7 MHz. In embodiments, the carrier frequency may be from about AM 540 to about AM 1700. In embodiments, the carrier frequency may be from about AM 500 to about AM 1750. In embodiments, the carrier frequency may be less-than-or-equal-to about 3.5, 4, 6, 10, or 60 MHz. In embodiments, the carrier frequency may be from about 80 MHz to about 200 MHz. In certain embodiments, due to aliasing, aspects of the radio signal 172 can be detected and utilized at selected fractions of the carrier frequency, allowing for matching the radio signal 172 even though sampling is at a lower rate than the carrier frequency. In certain embodiments, the sampling rate is at least half the rate of the carrier frequency. In certain embodiments, the sampling rate is at least one-quarter the rate of the carrier frequency.

While FIG. 1 depicts the transmitter 174 as an AM radio station tower, it is to be understood embodiments of the current disclosure may utilize any suitable radio wave, e.g., FM, WWV, aircraft navigation systems such as instrument landing systems (ILSs), VHF omnidirectional range (VORs), non-directional beacons, tactical air navigation systems (TACANs), Long Range Navigation (LORAN), and/or the like. Further, embodiments of the current disclosure are not limited to land-based electrical grids. For example, embodiments of the current disclosure are applicable to electrical systems on ships, planes, vehicles, space stations, and/or the like. Further, the radio signal 172 may be an injected signal, e.g., purposeful use of a transmitter to impinge the radio signal 172 on the electrical grid 158. Non-limiting use cases for an injected signal include electrical grids located in mines and/or buildings, facilities, and/or other environments where standard AM radio station signals do not sufficiently penetrate.

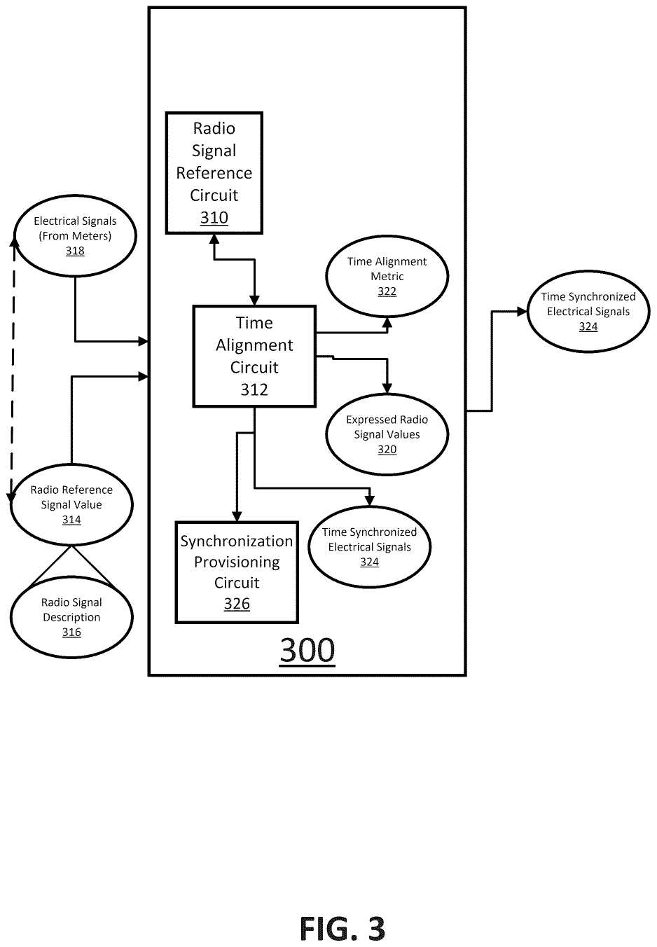

Referring now to FIG. 3, an apparatus 300 for synchronizing electrical meters 110, 112, 114, 116, 118, and 120 (FIG. 1) is shown in accordance with embodiments of the current disclosure. The apparatus 300 may form part of the one or more servers 168, one or more of the meters 110, 112, 114, 116, 118, and 120, and/or any other computing device disclosed herein. The apparatus 300 includes a radio signal reference circuit 310 (corresponding to 122 in FIG. 1) and a time alignment circuit 312 (corresponding to 124 in FIG. 1).

The radio signal reference circuit 310 is structured to interpret a reference radio signal value 314 (corresponding to radio signal 172 in FIG. 1) including a description 316 the radio signal 172 (FIG. 1) from the transmitter 174 (FIG. 1). In embodiments, the radio reference signal value 314 may be generated by receiving the radio signal (172) at an antenna 176 (FIG. 1) in electronic communication with or forming part of apparatus 300.

The time alignment circuit 312 is structured to interpret the plurality of electrical signals 318 (e.g., the readings) from the plurality of meters 110, 112, 114, 116, 118, 120 and determine an expressed radio signal value 320 for each of the plurality of electrical meters 110, 112, 114, 16, 118, 120 by processing the corresponding electrical signal 318 to determine a time alignment metric 322 in response to the reference radio signal value 314 and the expressed radio signal value 320 for each of the plurality of electrical meters 110, 112, 114, 116, 118, 120.

In embodiments, the time alignment circuit 312 is structured to process the corresponding electrical signal 318 to determine the expressed radio signal value by filtering the corresponding electrical signal 318 via a band pass filter, demodulating the corresponding electrical signal 318; and/or filtering the corresponding electrical signal 318 with a low pass filter.

In embodiments, the time alignment circuit 312 may be disposed in a housing of at least one of the plurality of electrical meters 110, 112, 114, 116, 118, 120. In embodiments, the time alignment circuit 312 may be disposed in at least one server and/or other computing device that is distinct from the electrical meters 110, 112, 114, 116, 118, 120; for example, in the one or more servers 168 (FIG. 1).

In embodiments, the time alignment metric 322 may be and/or include a point-level metric, a global-meter-level metric, a bucketed metric, and/or be based at least in part on a root-mean-square. In embodiments, the time alignment metric 322 may be based on offsets between a standard radio signal value and the expressed radio signal at either the individual point level (e.g., each data point is compared and offset); at the global meter level (e.g., an entire sequence is offset by the value that provides the best overall match for those points); bucketed (e.g., sequences, selected time periods, event periods, are offset together, but each offset may be different for each bucketed data set); and/or an error term (e.g., a root-mean-square).

The time alignment circuit 312 is further structured to determine a time synchronized electrical signal 324 for each of the plurality of electrical meters 110, 112, 114, 116, 118, 120 in response to the time alignment metric 322.

In embodiments, the apparatus 300 may further include a synchronization provisioning circuit 326 structured to transmit the time synchronized electrical signal 324 for each of the plurality of electrical meters 110, 112, 114, 116, 118, 120. In embodiments, the time synchronized electrical signal 324 may be transmitted to another circuit within the same computing device and/or a different computing device. In embodiments, the time synchronized electrical signal 324 may be used to generate graphics that depict the readings from the meters 110, 112, 114, 116, 118, 120 in an aligned format.

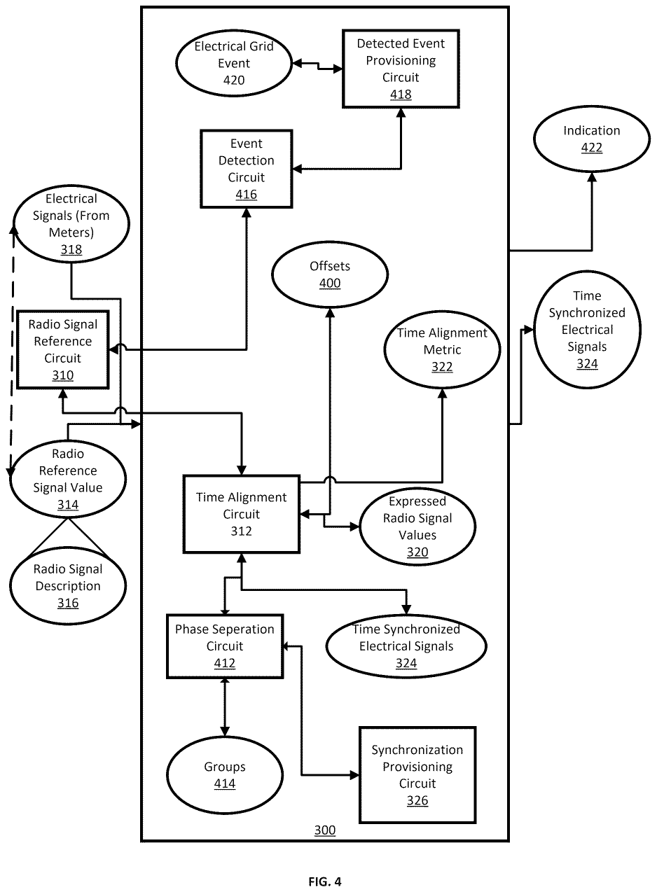

Illustrated in FIG. 4 is another embodiment of the apparatus 300 wherein the time alignment circuit 312 is further structured to determine offsets 410 between the reference radio signal value 314 and the expressed radio signal value 320 for each of the plurality of electrical meters 110, 112, 114, 116, 118, 120, wherein the time alignment metric 322 is based at least in part on the offsets 400.

In embodiments, the electrical signals 318 interpreted by the time alignment circuit 312 may be real-time and/or near real-time signals, e.g., the electrical signals 318 may be received by the apparatus 300 without having to retrieve them from a database. In embodiments, the electrical signals 318 may be historical data, e.g., stored in and retrieved from a database. For example, embodiments of the apparatus 300 may perform post-processing of electrical signals 318 stored in a database for minutes, hours, data, weeks, months, years, decades, centuries, etc.

In embodiments, the apparatus 300 further includes a phase separation circuit 412 structured to group the time synchronized electrical signals, e.g., into one or more groups/buckets 414, for the electrical meters 110, 112, 114, 116, 118, 120 based at least in part on the plurality of phases.

In embodiments, the apparatus 300 may further include an event detection circuit 416, and a detected event provisioning circuit 418. The event detection circuit 416 is structured to determine an electrical grid event 420 based at least in part on the time synchronized electrical signal 324 for each of the plurality of electrical meters 110, 112, 114, 116, 118, 120; and the detected event provisioning circuit 418 is structured to transmit an indication 422 of the electrical grid event 420. In embodiments, the electrical grid event 420 may corresponds to a power outage, a power level surge, a power level decrease, a change in impedance, a change in voltage, a change in current, and/or any other type of event visible within the electrical signals 318. Non-limiting examples of events include: vegetation events, e.g., leaves and/or branches touching power lines and/or other grid equipment; ground-to-line events, e.g., a downed power line; line-to-line events, e.g., touching power lines; loose connections on transformers and/or power lines; corrosion build-up; ice storms; substation malfunctions; and/or the like.

In embodiments, the event detection circuit 416 may include one or more triggers structured to capture snapshots (as disclosed herein) of a meter's reading upon the detection of an event 420. Such snapshots may extend for one or more seconds, minutes, hours, days, weeks, and/or years after the detection of an event. Embodiments of the current disclosure may also provide for a rolling cache, e.g., a buffer, where historical data may be store for seconds, minutes, hours, days, weeks, and/or years prior to the occurrence of an event, where such historical data may be included in the captured snapshots corresponding to an event. In embodiments, the rolling cache may be from about 0.5 seconds to about 1 second, and the post-event snapshots may cover from about 0.5 seconds to about 3 seconds. Snapshots may also be manually triggered.

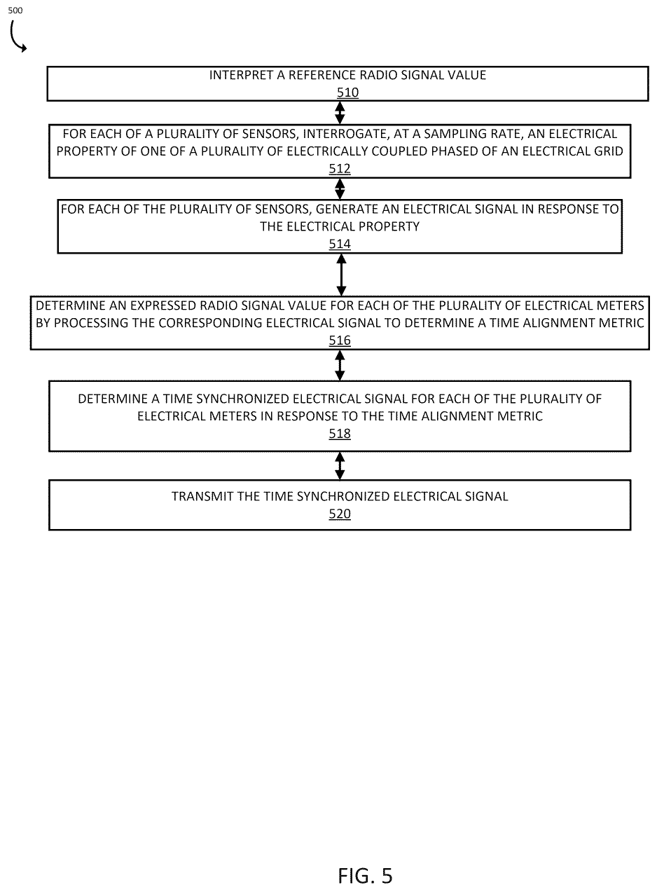

Illustrated in FIG. 5 is a method 500 for synchronizing electrical meters 110, 112, 114, 116, 118, and 120, in accordance with embodiments of the current disclosure. The method 500 may be performed by apparatus 300 (FIG. 3), the one or more servers 168 (FIG. 1), and/or any other computing device disclosed herein. The method 500 includes interpreting 510 a reference radio signal value 314 (FIG. 3) that includes a description of a radio signal 172 (FIG. 1) from a transmitter 174 (FIG. 1) that electrically impinges on an electrical grid 158 (FIG. 1). The method 500 further includes, for each of a plurality of sensors, e.g., meters 110, 112, 114, 116, 118, and 120, interrogating 512, at a sampling rate, an electrical property of one 216 (FIG. 2) of a plurality of electrically coupled phases 134 (FIG. 2) of an electrical grid 158 (FIG. 1). The method 500 further includes, for each of the plurality of sensors, generating 514 an electrical signal in response to the electrical property.

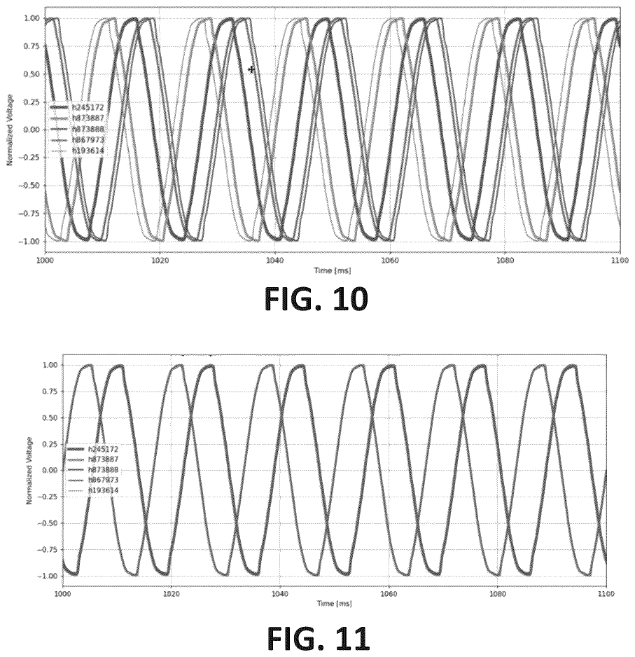

The method 500 further includes determining 516 an expressed radio signal value 320 (FIG. 3) for each of the plurality of electrical meters 110, 112, 114, 116, 118, and 120 (FIG. 10 by processing the corresponding electrical signal to determine a time alignment metric 322 in response to the reference radio signal value 314 and the expressed radio signal value 320 for each of the plurality of electrical meters 110, 112, 114, 116, 118, and 120.

The method 500 further includes determining 518 a time synchronized electrical signal 324 (FIG. 3) for each of the plurality of electrical meters 110, 112, 114, 116, 118, and 120 (FIG. 1) in response to the time alignment metric 322 (FIG. 3). In embodiments, the method 500 further includes transmitting 520 the time synchronized electrical signal.

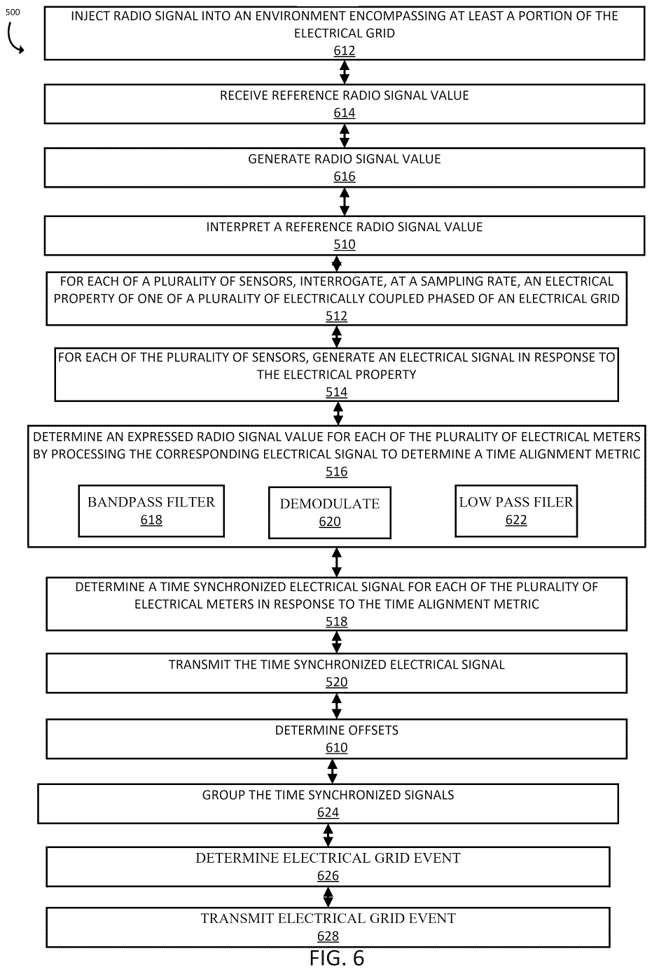

As shown in FIG. 6, in embodiments, the method 500 further includes determining 610 offsets 410 (FIG. 4) between the reference radio signal value 314 (FIG. 4) and the expressed radio signal value 320 (FIG. 4) for each of the plurality of electrical meters 110, 112, 114, 116, 118, and 120. In such embodiments, processing, e.g., 516, the corresponding electrical signal to determine a time alignment metric 322 (FIG. 4) is based at least in part on the offsets 410 (FIG. 4).

In embodiments, the method 500 further includes injecting 612 the radio signal into an environment encompassing at least a portion of the electrical grid 158 (FIG. 1). In embodiments, the method 500 may further include receiving 614 the radio signal via a plurality of antenna each forming part of one of the plurality of electrical meters 110, 112, 114, 116, 118, and 120. The method 500 may include generating the reference radio signal value in response to the radio signal. The operation to inject the radio signal may utilize a dedicated device, for example a beacon or dedicated transmitter, and/or may utilize an existing transmitter (e.g., an AM radio tower) that provides an additional or alternative transmission, for example at certain times of day and/or at selected frequencies that will not interfere with other operations of the transmitter, to provide a radio signal to be utilized for operations herein.

In embodiments, processing, e.g., 516, the corresponding electrical signal to determine the expressed radio signal value may include filtering 618 the corresponding electrical signal via a band pass filter, demodulating 620 the corresponding electrical signal, and/or filtering 622 the corresponding electrical signal with a low pass filter.

The method 500 may include grouping 624 the time synchronized electrical signals 324 (FIG. 4) for the electrical meters 110, 112, 114, 116, 118, and 120 based at least in part on the plurality of phases.

In embodiments, the method 500 include determining 626 an electrical grid event 420 (FIG. 4) based at least in part on the time synchronized electrical signal 324 (FIG. 4) for each of the plurality of electrical meters 110, 112, 114, 116, 118, and 120. The method 500 may include transmitting 628 an indication 422 (FIG. 4) of the electrical grid event 420 (FIG. 4).

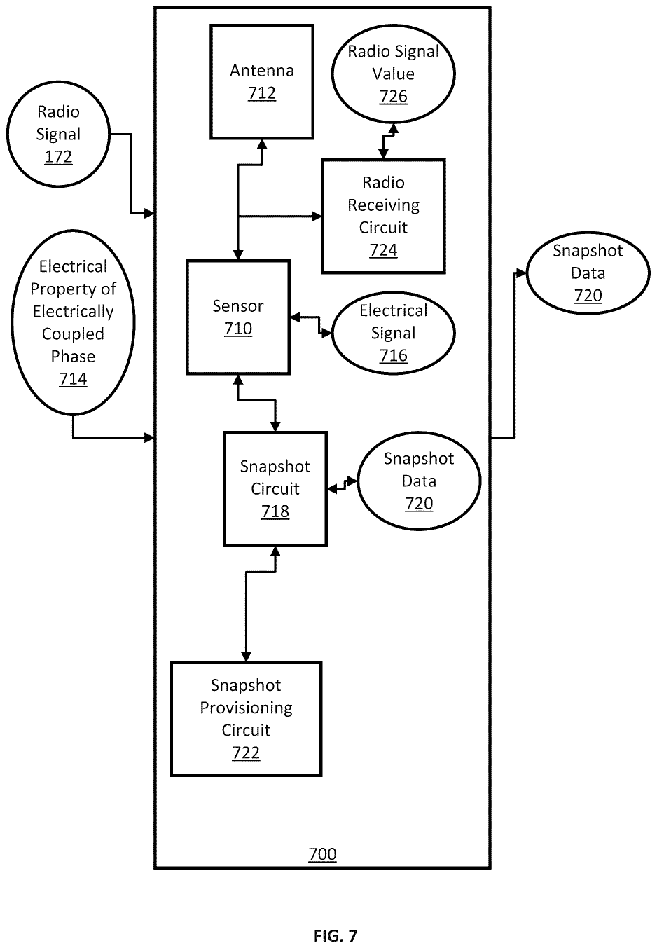

Referring now to FIG. 7, embodiments of the current disclosure may provide for an electrical meter 700 that includes a sensor 710 and an antenna 712 structured to receive the radio signal 172 (also shown in FIG. 1). In such embodiments, the sensor 710 is structured to interrogate the electrical property 714 of the electrically coupled phase at the sampling rate and generate the electrical signal 716 in response to the electrical property 714. The meter 700 may further include a snapshot circuit 718 structured to generate snapshot data 720, also referred to herein as a snapshot, based at least in part on the radio signal 172 and the electrical signal 716. The meter 700 may further include a snapshot provisioning circuit 722 structured to transmit the snapshot data 720, e.g., to the one or more servers 168 (FIG. 1). Additionally, it is to be understood that the antenna 712, and/or snapshot circuit 718 and snapshot provisioning circuit 722 may be integrated with the apparatus 300 (FIG. 3) and the circuits disclosed herein as forming part of the apparatus 300. In embodiments, the snapshot data 720 may include senser values paired to radio signal values. As will be appreciated, pairing of the radio signal values received from the antenna 712 may mitigate and/or avoid the need to filter the radio signal out of the meter readings.

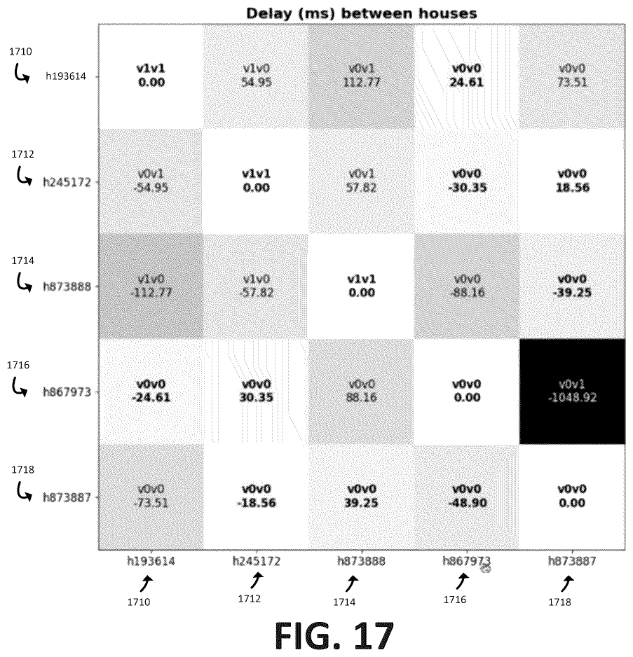

FIG. 17 depicts a chart showing delay/offsets 400 (FIG. 4) between five (5) meters 1710, 1712, 1714, 1716, and 1718 within an electrical grid.

In embodiments, the apparatus 700 may further include a radio receiving circuit 724 structured to generate a reference radio signal value 726 in response to the radio signal 172.

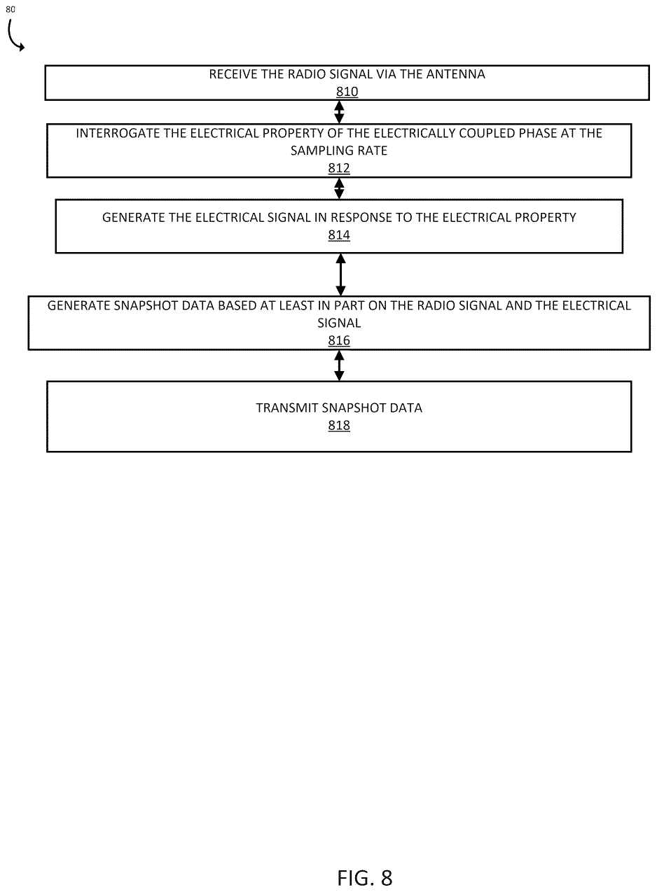

Illustrated in FIG. 8 is a method 800 for generating a snapshot of an electrical main, in accordance with embodiments of the current disclosure. The method 800 may be performed by apparatuses 700 (FIG. 7) and/or any other computing device disclosed herein. Additionally, in embodiments that integrate the antenna 712, and/or snapshot circuit 718 and snapshot provisioning circuit 722 with the apparatus 300 (FIG. 3) and/or one or more of the circuits disclosed herein as forming part of the apparatus 300, such embodiments may perform one or more processes forming part of methods 500 and/or 300.

Accordingly, the method 800 includes receiving 810, via the antenna 712 (FIG. 7) of an electrical meter 700 (FIG. 7), a radio signal 172 from a transmitter, e.g., 174 (FIG. 1). The method 800 further includes interrogating 812, via the sensor 710 (FIG. 7) of the electrical meter 700 (FIG. 7), an electrical property of an electrically coupled phase, of a plurality of phases of an electrical grid 158 (FIG. 1), at the sampling rate, as disclosed herein. The method 800 further includes generating 814, via the sensor 710, an electrical signal 716 (FIG. 7) in response to the electrical property 714 (FIG. 7). The method 800 further includes generating 816 snapshot data 720 (FIG. 7) based at least in part on the radio signal 172 (FIG. 7) and the electrical signal 716 (FIG. 7). The method 800 further includes transmitting 818 the snapshot data 720 (FIG. 7).

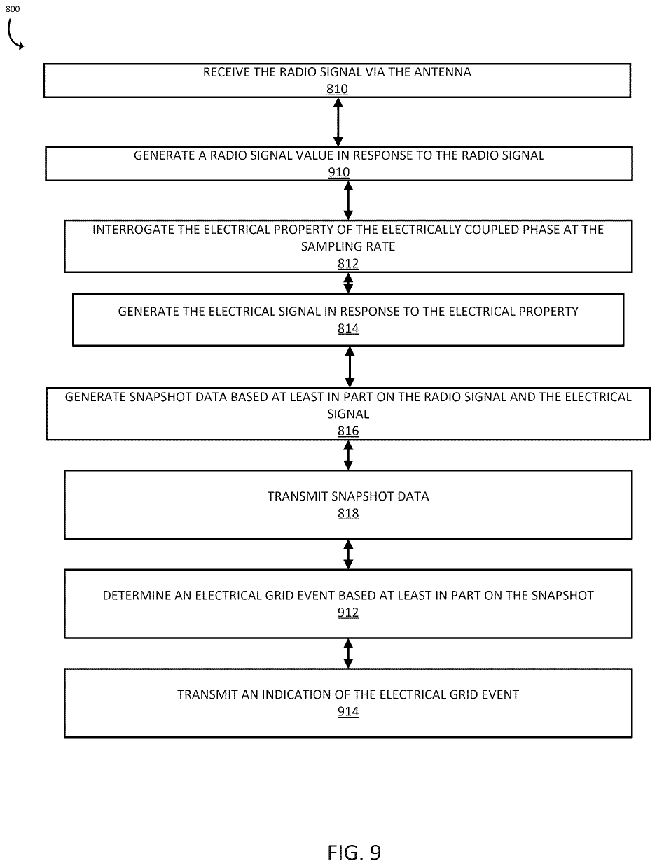

As shown in FIG. 9, in embodiments, the method 800 may further include generating 910 a radio signal value in response to the radio signal, wherein the snapshot data includes the radio signal value. In embodiments, the snapshot further includes the electrical signal. In embodiments, the snapshot is structured to map the radio signal value to the electrical signal. In embodiments, the snapshot includes the electrical signal.

The method 800 may further include determining 912 an electrical grid event based at least in part on the snapshot; and transmitting 914 an indication of the electrical grid event.

FIG. 10 depicts a capture of readings from five (5) meter (disposed on mains of various properties in a test neighborhood) using network time protocol (NTP) as a basis for synchronizing the signals from various meters within a same electrical grid. In particular, the capture shown in FIG. 10 is a three (3) second MHz snapshot. As can be seen, the NTP protocol, as of the time of the current disclosure, does not provide the needed precision to generate a metric for aligning the signals.

FIG. 11, in contrast to FIG. 10, depicts the alignment of the same five (5) meters of the example of FIG. 10 using an AM radio signal, as disclosed herein, to align the signals. Once aligned, it can be seen that the five (5) meters are divided into two groups (represented by the two waves), where each group is connected to a different phase of the power grid.

Embodiments of the current disclosure may utilize a wide variety of methods and approaches for obtaining the radio signal embedded within the meter readings. For example, in embodiments, a radio signal may be directly filtered out of the meter readings it is below the Nyquist for the sampling rate. As will be appreciated, however, radio signals having carrier frequencies above the Nyquist frequency of the sampling rate of the meters 110, 112, 114, 116, 118, and 120 may be obtained due to aliasing. For example, in embodiments, the sampling rate may be about one MHz with a Nyquist frequency of about 500 Mhz where it is desirable to use AM 680 (680 KHz) to synchronize the meter readings. In such an example, the AM 680 signal can be obtained by filtering it out from its aliases at and/or about 320 KHz, e.g., then using a bandpass filter of about eight (8 to about ten (10) KHz) centered at about 320 KHz. The filtered signal may then be mixed with the carrier frequency and its quadrature to demodulate the signal down to DC, and then use a low-pass filter to obtain the signal used for synchronizing the meters 110, 112, 114, 116, 118, and 120. It is to be understood that the different signals can be obtained by shifting the center of the bandpass filter. Further, embodiments of the bandpass filter may vary in width.

Embodiments of the current disclosure may include variable filters and/or fixed filters. For example, embodiments of the apparatuses 300 and/or 700 may include fixed filters each structured to filter out a predefined radio frequency, e.g., known AM radio stations broadcasting within a portion of an electrical grid. Further, embodiments of the current disclosure may synchronize the meter readings using multiple radio signals. As will be appreciated, use of multiple radio signals may provide for improved accuracy in synchronizing meter readings across a grid as the differences in delays between the expressed radio signals, e.g., the radio signals as seen by each meter, can be averaged.

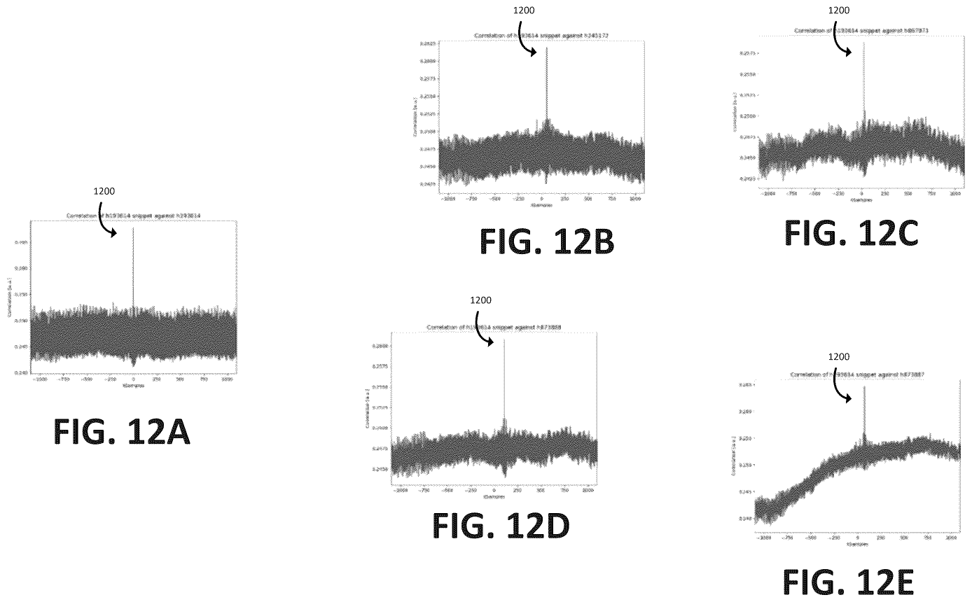

FIGS. 12A-12E depict further aspects of filtering out the radio signal from the meter readings and using the resulting signals to align meter readings. FIG. 12A illustrates a baseline example of correlating a snapshot of an initial test meter with itself where the spike 1200 at 0 represents no delay. FIGS. 12B-12E depict correlations between the initial test meter and other test meters where the shift in the spike 1200 away from 0 indicates relative delay between the test meters. Accounting for the delay results in the alignment of the meter readings as shown in FIG. 11. As will be understood, embodiments of the current disclosure may account for phase-shifts in the meter readings due to capacitor banks and/or other electrical devices, and/or due to inherent capacitive effects of lines and other components in the system.

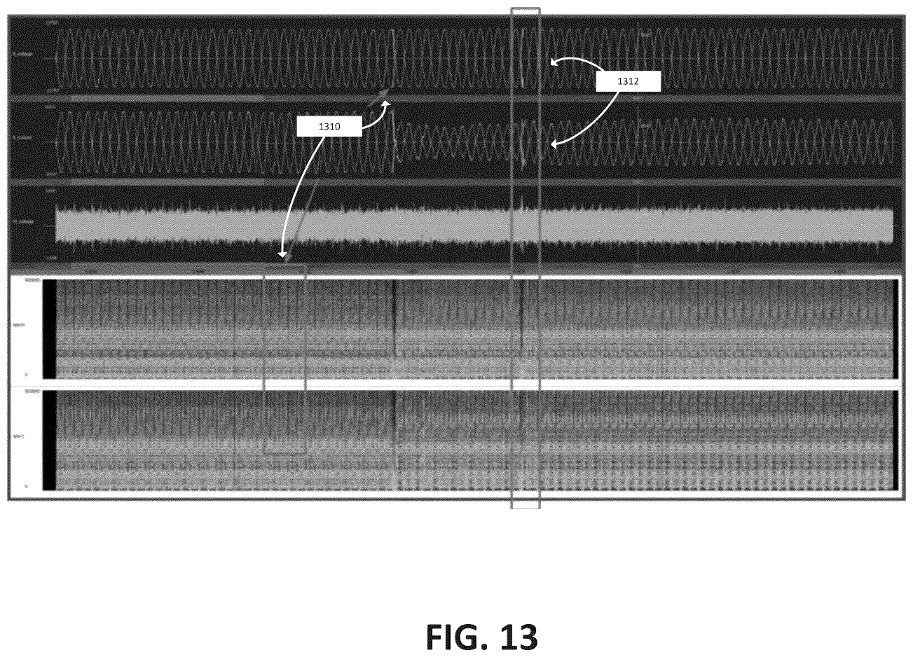

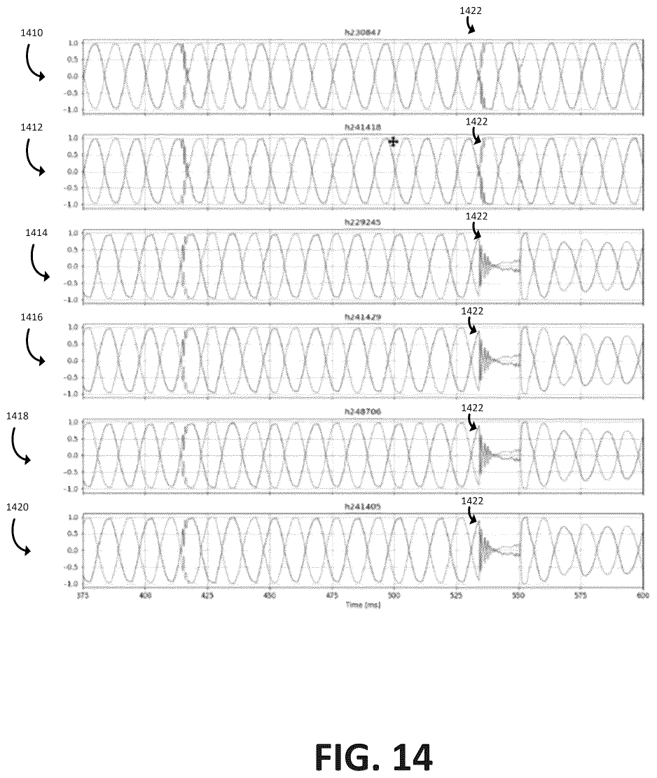

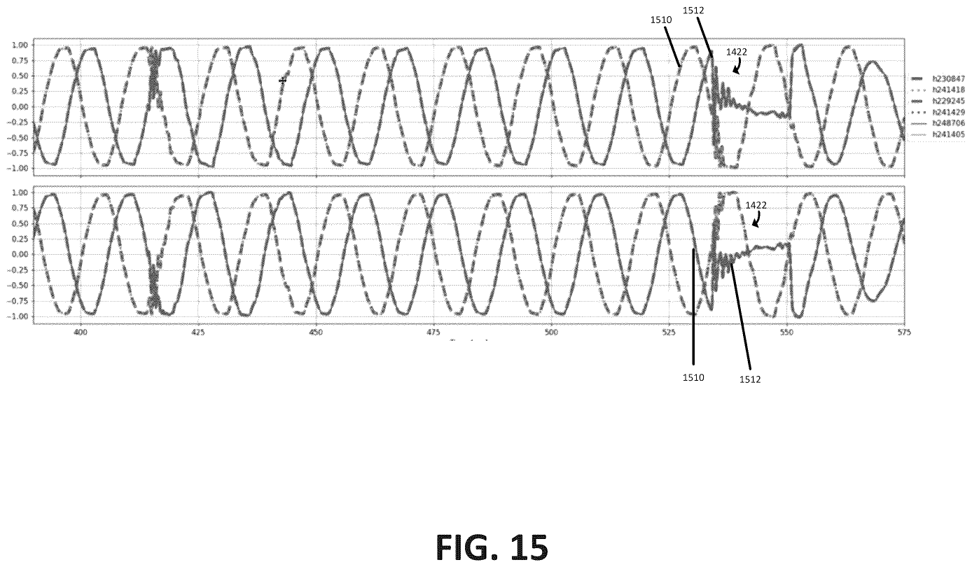

As disclosed herein, embodiments of the current disclosure provide for the ability to detect events, e.g., faults, within the electrical grid and, in certain aspects, localize the events. For example, FIG. 13 depicts data collected from six (6) test meters located near a known event, e.g., fault. While certain items are discernable, e.g., a MHz burst 1310 and a distortion 1312 are visible, it is difficult and/or impossible to confidentially identify which meters experiences the fault and when. In contrast, FIG. 14 shows alignment of the six (6) meters, e.g., 1410, 1412, 1416, 1418, and 1420 (each depicting one (1) meter connected to two (2) mains), where it becomes clear that meters 1414, 1416, 1418, and 1420 significantly experienced the event 1422, while meters 1410 and 1412 moderately experienced the event. Further, it can be seen that meters 1410 and 1412 are on a same first phase 1510 of the grid whereas meters 1414, 1416, 1418, and 1420 are on a different second phase 1512 of the gird, as best seen in FIG. 15, which depicts the meters 1410, 1412, 1416, 1418, and 1420 overlayed on each other.

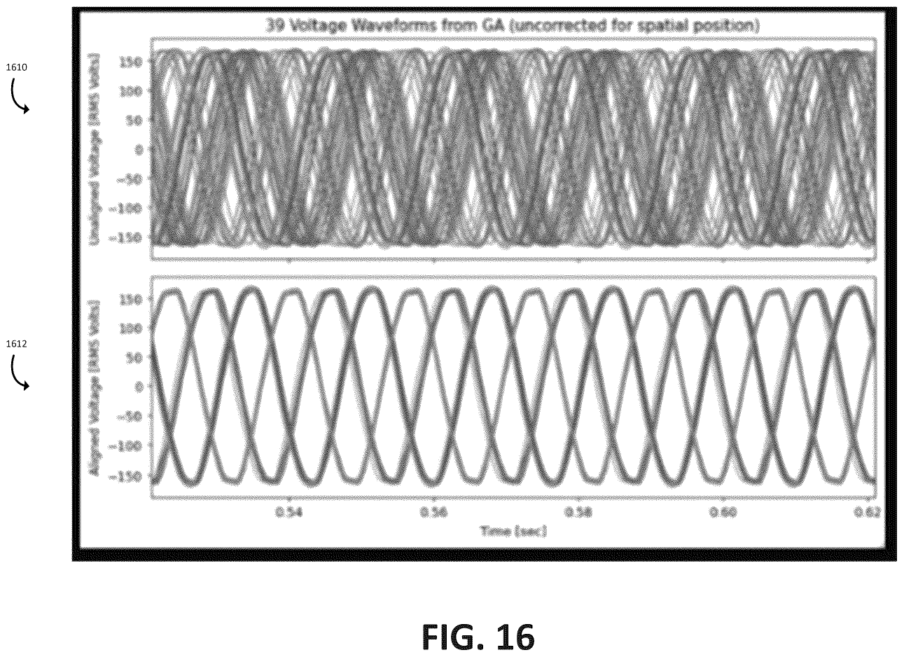

FIG. 16 depicts an example readout of thirty-nine (39) test meters where chart 1610 shows the unaligned readings and chart 1612 shows the aligned readings. As will be appreciated, alignment of the meters shows that each of the 3-phases of the grid is coupled to one of the meters. Accordingly, embodiments of the current disclosure provide for the ability to determine the magnitude and/or effect of an event on each phase of a power grid and/or each phase powering a facility. For example, embodiments of the current disclosure improve the ability to determine the effects of electromagnetic noise and/or interference from known sources and/or improve the ability to localize previously unknown sources, e.g., machinery and/or equipment in an industrial plant and/or on an aircraft.

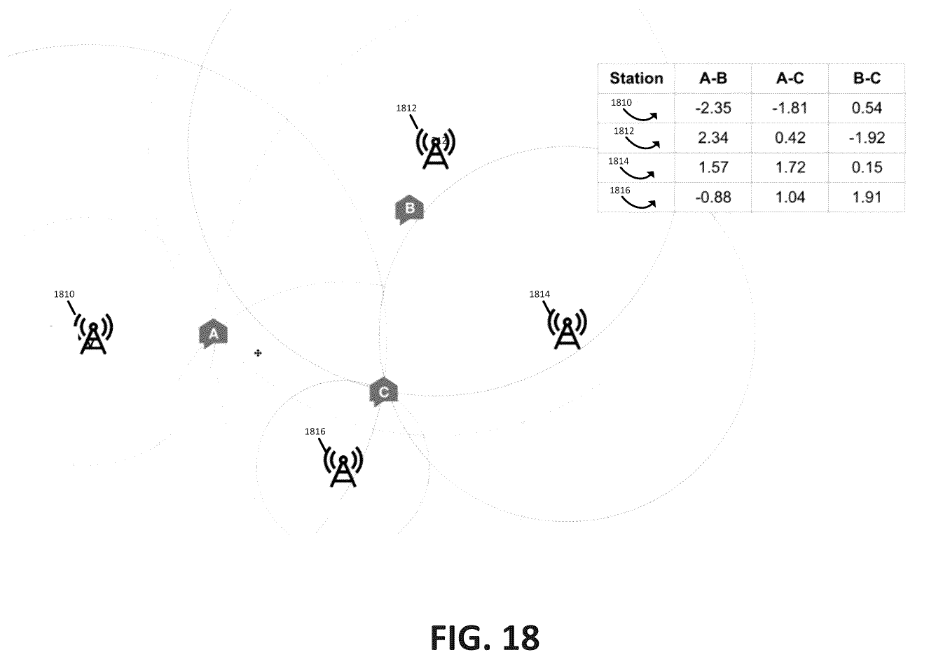

FIG. 18 illustrates another use case of embodiments of the current disclosure in which the delay from radio stations 1810, 1812, 1814, and 1816 can be used to localize meters A, B, and C (in adherence with consumer privacy laws and/or best practices), and/or to localize events via triangulation (or similar distancing algorithms, for example which may consider the layout of power lines as additional positioning constraints, and which can allow for position determination with fewer than three radio station delay signals), and/or suitable methos of localizing objects via receipt of one or more radio waves by one or more antennas.

The methods and systems described herein, e.g., apparatuses 300 (FIGS. 3 and 4), method 500 (FIGS. 5 and 6), apparatus 700 (FIG. 7), may be deployed in part or in whole through a machine (such as servers 169 (FIG. 1)) having a computer, computing device, processor, circuit, e.g., circuits 310, 312, 326 (FIG. 3), and/or server that executes computer readable instructions, program codes, instructions, and/or includes hardware configured to functionally execute one or more operations of the methods and systems herein. The terms computer, computing device, processor, circuit, and/or server, (“computing device”) as utilized herein, should be understood broadly.

An example computing device, such as apparatus 300 (FIG. 3), includes a computer of any type, capable to access instructions stored in communication thereto such as upon a non-transient computer readable medium, whereupon the computer performs operations of the computing device upon executing the instructions. In certain embodiments, such instructions themselves comprise a computing device. Additionally or alternatively, a computing device, e.g., apparatus 700, may be a separate hardware device, one or more computing resources distributed across hardware devices, and/or may include such aspects as logical circuits, embedded circuits, sensors, actuators, input and/or output devices, network and/or communication resources, memory resources of any type, processing resources of any type, and/or hardware devices configured to be responsive to determined conditions to functionally execute one or more operations of systems and methods herein.

Network, e.g., 170 (FIG. 1), and/or communication resources include, without limitation, local area network, wide area network, wireless, internet, or any other known communication resources and protocols. Example and non-limiting hardware and/or computing devices include, without limitation, a general-purpose computer, a server, an embedded computer, a mobile device, a virtual machine, and/or an emulated computing device. A computing device may be a distributed resource included as an aspect of several devices, included as an interoperable set of resources to perform described functions of the computing device, such that the distributed resources function together to perform the operations of the computing device. In certain embodiments, each computing device may be on separate hardware, and/or one or more hardware devices may include aspects of more than one computing device, for example as separately executable instructions stored on the device, and/or as logically partitioned aspects of a set of executable instructions, with some aspects comprising a part of one of a first computing device, and some aspects comprising a part of another of the computing devices.

A computing device may be part of a server, e.g., 169 (FIG. 1), client, network infrastructure, mobile computing platform, stationary computing platform, or other computing platform. A processor may be any kind of computational or processing device capable of executing program instructions, codes, binary instructions and the like. The processor may be or include a signal processor, digital processor, embedded processor, microprocessor or any variant such as a co-processor (math co-processor, graphic co-processor, communication co-processor and the like) and the like that may directly or indirectly facilitate execution of program code or program instructions stored thereon. In addition, the processor may enable execution of multiple programs, threads, and codes. The threads may be executed simultaneously to enhance the performance of the processor and to facilitate simultaneous operations of the application. By way of implementation, methods, program codes, program instructions and the like described herein may be implemented in one or more threads. The thread may spawn other threads that may have assigned priorities associated with them; the processor may execute these threads based on priority or any other order based on instructions provided in the program code. The processor may include memory that stores methods, codes, instructions and programs as described herein and elsewhere. The processor may access a storage medium through an interface that may store methods, codes, and instructions as described herein and elsewhere. The storage medium associated with the processor for storing methods, programs, codes, program instructions or other type of instructions capable of being executed by the computing or processing device may include but may not be limited to one or more of a CD-ROM, DVD, memory, hard disk, flash drive, RAM, ROM, cache and the like.

A processor may include one or more cores that may enhance speed and performance of a multiprocessor. In embodiments, the process may be a dual core processor, quad core processors, other chip-level multiprocessor and the like that combine two or more independent cores (called a die).

The methods and systems described herein may be deployed in part or in whole through a machine that executes computer readable instructions on a server, client, firewall, gateway, hub, router, or other such computer and/or networking hardware. The computer readable instructions may be associated with a server that may include a file server, print server, domain server, internet server, intranet server and other variants such as secondary server, host server, distributed server and the like. The server may include one or more of memories, processors, computer readable transitory and/or non-transitory media, storage media, ports (physical and virtual), communication devices, and interfaces capable of accessing other servers, clients, machines, and devices through a wired or a wireless medium, and the like. The methods, programs, or codes as described herein and elsewhere may be executed by the server. In addition, other devices required for execution of methods as described in this application may be considered as a part of the infrastructure associated with the server.

The server may provide an interface to other devices including, without limitation, clients, other servers, printers, database servers, print servers, file servers, communication servers, distributed servers, and the like. Additionally, this coupling and/or connection may facilitate remote execution of instructions across the network. The networking of some or all of these devices may facilitate parallel processing of program code, instructions, and/or programs at one or more locations without deviating from the scope of the disclosure. In addition, all the devices attached to the server through an interface may include at least one storage medium capable of storing methods, program code, instructions, and/or programs. A central repository may provide program instructions to be executed on different devices. In this implementation, the remote repository may act as a storage medium for methods, program code, instructions, and/or programs.

The methods, program code, instructions, and/or programs may be associated with a client that may include a file client, print client, domain client, internet client, intranet client and other variants such as secondary client, host client, distributed client and the like. The client may include one or more of memories, processors, computer readable transitory and/or non-transitory media, storage media, ports (physical and virtual), communication devices, and interfaces capable of accessing other clients, servers, machines, and devices through a wired or a wireless medium, and the like. The methods, program code, instructions, and/or programs as described herein and elsewhere may be executed by the client. In addition, other devices required for execution of methods as described in this application may be considered as a part of the infrastructure associated with the client.

The client may provide an interface to other devices including, without limitation, servers, other clients, printers, database servers, print servers, file servers, communication servers, distributed servers, and the like. Additionally, this coupling and/or connection may facilitate remote execution of methods, program code, instructions, and/or programs across the network. The networking of some or all of these devices may facilitate parallel processing of methods, program code, instructions, and/or programs at one or more locations without deviating from the scope of the disclosure. In addition, all the devices attached to the client through an interface may include at least one storage medium capable of storing methods, program code, instructions, and/or programs. A central repository may provide program instructions to be executed on different devices. In this implementation, the remote repository may act as a storage medium for methods, program code, instructions, and/or programs.

The methods and systems described herein may be deployed in part or in whole through network infrastructures. The network infrastructure may include elements such as computing devices, servers, routers, hubs, firewalls, clients, personal computers, communication devices, routing devices and other active and passive devices, modules, and/or components as known in the art. The computing and/or non-computing device(s) associated with the network infrastructure may include, apart from other components, a storage medium such as flash memory, buffer, stack, RAM, ROM and the like. The methods, program code, instructions, and/or programs described herein and elsewhere may be executed by one or more of the network infrastructural elements.

The methods, program code, instructions, and/or programs described herein and elsewhere may be implemented on a cellular network having multiple cells. The cellular network may either be frequency division multiple access (FDMA) network or code division multiple access (CDMA) network. The cellular network may include mobile devices, cell sites, base stations, repeaters, antennas, towers, and the like.

The methods, program code, instructions, and/or programs described herein and elsewhere may be implemented on or through mobile devices. The mobile devices may include navigation devices, cell phones, mobile phones, mobile personal digital assistants, laptops, palmtops, netbooks, pagers, electronic books readers, music players and the like. These devices may include, apart from other components, a storage medium such as a flash memory, buffer, RAM, ROM and one or more computing devices. The computing devices associated with mobile devices may be enabled to execute methods, program code, instructions, and/or programs stored thereon. Alternatively, the mobile devices may be configured to execute instructions in collaboration with other devices. The mobile devices may communicate with base stations interfaced with servers and configured to execute methods, program code, instructions, and/or programs. The mobile devices may communicate on a peer-to-peer network, mesh network, or other communications network. The methods, program code, instructions, and/or programs may be stored on the storage medium associated with the server and executed by a computing device embedded within the server. The base station may include a computing device and a storage medium. The storage device may store methods, program code, instructions, and/or programs executed by the computing devices associated with the base station.

The methods, program code, instructions, and/or programs may be stored and/or accessed on machine readable transitory and/or non-transitory media that may include: computer components, devices, and recording media that retain digital data used for computing for some interval of time; semiconductor storage known as random access memory (RAM); mass storage typically for more permanent storage, such as optical discs, forms of magnetic storage like hard disks, tapes, drums, cards and other types; processor registers, cache memory, volatile memory, non-volatile memory; optical storage such as CD, DVD; removable media such as flash memory (e.g. USB sticks or keys), floppy disks, magnetic tape, paper tape, punch cards, standalone RAM disks, Zip drives, removable mass storage, off-line, and the like; other computer memory such as dynamic memory, static memory, read/write storage, mutable storage, read only, random access, sequential access, location addressable, file addressable, content addressable, network attached storage, storage area network, bar codes, magnetic ink, and the like.

Certain operations described herein include interpreting, receiving, and/or determining one or more values, parameters, inputs, data, or other information (“receiving data”). Operations to receive data include, without limitation: receiving data via a user input; receiving data over a network of any type; reading a data value from a memory location in communication with the receiving device; utilizing a default value as a received data value; estimating, calculating, or deriving a data value based on other information available to the receiving device; and/or updating any of these in response to a later received data value. In certain embodiments, a data value may be received by a first operation, and later updated by a second operation, as part of the receiving a data value. For example, when communications are down, intermittent, or interrupted, a first receiving operation may be performed, and when communications are restored an updated receiving operation may be performed.

Certain logical groupings of operations herein, for example methods or procedures of the current disclosure, are provided to illustrate aspects of the present disclosure. Operations described herein are schematically described and/or depicted, and operations may be combined, divided, re-ordered, added, or removed in a manner consistent with the disclosure herein. It is understood that the context of an operational description may require an ordering for one or more operations, and/or an order for one or more operations may be explicitly disclosed, but the order of operations should be understood broadly, where any equivalent grouping of operations to provide an equivalent outcome of operations is specifically contemplated herein. For example, if a value is used in one operational step, the determining of the value may be required before that operational step in certain contexts (e.g., where the time delay of data for an operation to achieve a certain effect is important), but may not be required before that operation step in other contexts (e.g. where usage of the value from a previous execution cycle of the operations would be sufficient for those purposes). Accordingly, in certain embodiments an order of operations and grouping of operations as described is explicitly contemplated herein, and in certain embodiments re-ordering, subdivision, and/or different grouping of operations is explicitly contemplated herein.

The methods and systems described herein may transform physical and/or or intangible items from one state to another. The methods and systems described herein may also transform data representing physical and/or intangible items from one state to another.

The methods and/or processes described above, and steps thereof, may be realized in hardware, program code, instructions, and/or programs or any combination of hardware and methods, program code, instructions, and/or programs suitable for a particular application. The hardware may include a dedicated computing device or specific computing device, a particular aspect or component of a specific computing device, and/or an arrangement of hardware components and/or logical circuits to perform one or more of the operations of a method and/or system. The processes may be realized in one or more microprocessors, microcontrollers, embedded microcontrollers, programmable digital signal processors or other programmable device, along with internal and/or external memory. The processes may also, or instead, be embodied in an application specific integrated circuit, a programmable gate array, programmable array logic, or any other device or combination of devices that may be configured to process electronic signals. It will further be appreciated that one or more of the processes may be realized as a computer executable code capable of being executed on a machine readable medium.

The computer executable code may be created using a structured programming language such as C, an object oriented programming language such as C++, or any other high-level or low-level programming language (including assembly languages, hardware description languages, and database programming languages and technologies) that may be stored, compiled or interpreted to run on one of the above devices, as well as heterogeneous combinations of processors, processor architectures, or combinations of different hardware and computer readable instructions, or any other machine capable of executing program instructions.

Thus, in one aspect, each method described above, and combinations thereof, may be embodied in computer executable code that, when executing on one or more computing devices, performs the steps thereof. In another aspect, the methods may be embodied in systems that perform the steps thereof, and may be distributed across devices in a number of ways, or all of the functionality may be integrated into a dedicated, standalone device or other hardware. In another aspect, the means for performing the steps associated with the processes described above may include any of the hardware and/or computer readable instructions described above. All such permutations and combinations are intended to fall within the scope of the present disclosure.

Additionally, and as described herein, machine learning models, such as those that may be employed in the time alignment circuit 312 (FIGS. 3 and 4), event detection circuit 416 (FIG. 4), snapshot circuit 718 (Fig, 7), may be trained using supervised learning or unsupervised learning. In supervised learning, a model is generated using a set of labeled examples, where each example has corresponding target label(s). In unsupervised learning, the model is generated using unlabeled examples. The collection of examples constructs a dataset, usually referred to as a training dataset. During training, a model is generated using this training data to learn the relationship between examples in the dataset. The training process may include various phases such as: data collection, preprocessing, feature extraction, model training, model evaluation, and model fine-tuning. The data collection phase may include collecting a representative dataset, typically from multiple users, that covers the range of possible scenarios and positions. The preprocessing phase may include cleaning and preparing the examples in the dataset and may include filtering, normalization, and segmentation. The feature extraction phase may include extracting relevant features from examples to capture relevant information for the task. The model training phase may include training a machine learning model on the preprocessed and feature-extracted data. Models may include support vector machines (SVMs), artificial neural networks (ANNs), decision trees, and the like for supervised learning, or autoencoders, Hopfield, restricted Boltzmann machine (RBM), deep belief, Generative Adversarial Networks (GAN), or other networks, or clustering for unsupervised learning. The model evaluation phase may include evaluating the performance of the trained model on a separate validation dataset to ensure that it generalizes well to new and unseen examples. The model fine-tuning may include refining a model by adjusting its parameters, changing the features used, or using a different machine-learning algorithm, based on the results of the evaluation. The process may be iterated until the performance of the model on the validation dataset is satisfactory and the trained model can then be used to make predictions.

In embodiments, trained models may be periodically fine-tuned for specific user groups, applications, and/or tasks. Fine-tuning of an existing model may improve the performance of the model for an application while avoiding completely retraining the model for the application.

In embodiments, fine-tuning a machine learning model may involve adjusting its hyperparameters or architecture to improve its performance for a particular user group or application. The process of fine-tuning may be performed after initial training and evaluation of the model, and it can involve one or more hyperparameter tuning and architectural methods.

Hyperparameter tuning includes adjusting the values of the model's hyperparameters, such as learning rate, regularization strength, or the number of hidden units. This can be done using methods such as grid search, random search, or Bayesian optimization. Architecture modification may include modifying the structure of the model, such as adding or removing layers, changing the activation functions, or altering the connections between neurons, to improve its performance.

Online training of machine learning models includes a process of updating the model as new examples become available, allowing it to adapt to changes in the data distribution over time. In online training, the model is trained incrementally as new data becomes available, allowing it to adapt to changes in the data distribution over time. Online training can also be useful for user groups that have changing usage habits of the stimulation device, allowing the models to be updated in almost real-time.

In embodiments, online training may include adaptive filtering. In adaptive filtering, a machine learning model is trained online to learn the underlying structure of the new examples and remove noise or artifacts from the examples.

Embodiments of the current disclosure are set forth in the following non-limiting examples, wherein one or more aspects of the disclosed embodiments, in whole or in part, may be combined with and/or embodied in one or more other aspects of the disclosed embodiments and/or any other embodiments disclosed herein.

An example embodiment includes a non-transitory computer-readable medium storing instructions that adapt at least one processor to: interpret a reference radio signal value including a description of a radio signal from a transmitter that electrically impinges on an electrical grid, the radio signal having a carrier frequency; for each of a plurality of sensors, interrogate, at a sampling rate, an electrical property of one of a plurality of electrically coupled phases of an electrical grid, wherein: each of the plurality of sensors forms part of one of a plurality of electrical meters disposed at distinct locations, each of the plurality of electrical meters is electrically coupled to one of the plurality of phases, and the sampling rate is at least equal to the carrier frequency; for each of the plurality of sensors, generate an electrical signal in response to the electrical property; determine an expressed radio signal value for each of the plurality of electrical meters by processing the corresponding electrical signal to determine a time alignment metric in response to the reference radio signal value and the expressed radio signal value for each of the plurality of electrical meters; determine a time synchronized electrical signal for each of the plurality of electrical meters in response to the time alignment metric; and transmit the time synchronized electrical signal.

In a further embodiment, the stored instructions further cause the at least one processor to: determine offsets between the reference radio signal value and the expressed radio signal value for each of the plurality of electrical meters, wherein processing the corresponding electrical signal to determine a time alignment metric is based at least in part on the offsets. In a further embodiment, the time alignment metric is at least one of: a point-level metric; a global-meter-level metric; a bucketed metric; or based at least in part on a root-mean-square. In a further embodiment, the carrier frequency is from about 275 kHz to about 1.75 MHz. In a further embodiment, the transmitter is an AM transmitter in electrical proximity to the electrical grid. In a further embodiment, the stored instructions further adapt the at least one processor to: inject the radio signal into an environment encompassing at least a portion of the electrical grid. In a further embodiment, the stored instructions further adapt the at least one processor to: receive the radio signal via a plurality of antenna each forming part of one of the plurality of electrical meters. In a further embodiment, the stored instructions further adapt the at least one processor to: generate the reference radio signal value in response to the radio signal. In a further embodiment, the stored instructions further adapt the at least one processor to determine the time synchronized electrical signal for each of the plurality of electrical meters in real-time. In a further embodiment, the corresponding electrical signal is historical data. In a further embodiment, the stored instructions further adapt the at least one processor to at least one of: filter the corresponding electrical signal via a band pass filter; demodulate the corresponding electrical signal; or filter the corresponding electrical signal with a low pass filter. In a further embodiment, the stored instructions further adapt the at least one processor to: group the time synchronized electrical signals for the electrical meters based at least in part on the plurality of phases. In a further embodiment, the at least one processor is disposed in a housing of at least one of the plurality of electrical meters. In a further embodiment, the at least one processor is disposed in at least one server distinct from the plurality of electrical meters. In a further embodiment, the stored instructions further adapt the at least one processor to: determine an electrical grid event based at least in part on the time synchronized electrical signal for each of the plurality of electrical meters; and transmit an indication of the electrical grid event. In a further embodiment, the electrical grid event corresponds to a power outage. In a further embodiment, the electrical grid event corresponds to at least one of: a power level surge; or a power level decrease. In a further embodiment, the electrical grid event corresponds to at least one of: a change in impedance; a change in voltage; or a change in current.

Another example embodiment includes a non-transitory computer-readable medium storing instructions that adapt at least one processor to: interrogate, via a sensor of an electrical meter, an electrical property of an electrically coupled phase, of a plurality of phases of an electrical grid, at a sampling rate, wherein the sampling rate is at least equal to a carrier frequency of a radio signal from a transmitter that electrically impinges on the electrical grid; generate, via the sensor, an electrical signal in response to the electrical property; interpret a reference radio signal value including a description of the radio signal; interpret a plurality of electrical signals, including the electrical signal, wherein each of the plurality of electrical signals is from a distinct one of a plurality of electrical meters disposed at distinct locations, wherein each of the plurality of electrical meters is electrically coupled to a phase of the plurality of phases of the electrical grid; determine an expressed radio signal value for each of the plurality of electrical meters by processing the corresponding electrical signal to determine a time alignment metric in response to the reference radio signal value and the expressed radio signal value for each of the plurality of electrical meters; determine a time synchronized electrical signal for each of the plurality of electrical meters in response to the time alignment metric; and transmit the time synchronized electrical signal for each of the plurality of electrical meters.

In a further embodiment, the stored instructions further adapt the at least one processor to: determine offsets between the reference radio signal value and the expressed radio signal value for each of the plurality of electrical meters, wherein the time alignment metric is based at least in part on the offsets. In a further embodiment the time alignment metric is at least one of: a point-level metric; a global-meter-level metric; a bucketed metric; or based at least in part on a root-mean-square. In a further embodiment the carrier frequency is from about 275 kHz to about 1.75 MHz. In a further embodiment, the transmitter is an AM transmitter in electrical proximity to the electrical grid. In a further embodiment, the radio signal is an injected signal. In a further embodiment, the stored instructions further adapt the at least one processor to: receive, via an antenna of the electrical meter, the radio signal. In a further embodiment, the stored in instructions further adapt the at least one processor to: generate the reference radio signal value in response to the radio signal. In a further embodiment, the determination of the time synchronized electrical signal for each of the plurality of electrical meters is in real-time. In a further embodiment, the corresponding electrical signal is historical data. In a further embodiment, the stored instructions further adapt the at least one processor to at least one of: filter the corresponding electrical signal via a band pass filter; demodulate the corresponding electrical signal; or filter the corresponding electrical signal with a low pass filter. In a further embodiment, the stored instructions further adapt the at least one processor to: group the time synchronized electrical signals for the electrical meters based at least in part on the plurality of phases. In a further embodiment, the stored instructions further adapt the at least one processor to: determine an electrical grid event based at least in part on the time synchronized electrical signal for each of the plurality of electrical meters; and transmit an indication of the electrical grid event. In a further embodiment, the electrical grid event corresponds to a power outage. In a further embodiment, the electrical grid event corresponds to at least one of: a power level surge; or a power level decrease. In a further embodiment, the electrical grid event corresponds to at least one of: a change in impedance; a change in voltage; or a change in current.

Another example embodiment includes a non-transitory computer-readable medium storing instructions that adapt at least one processor to: receive, via an antenna of an electrical meter, a radio signal from a transmitter; interrogate, via a sensor of the electrical meter, an electrical property of an electrically coupled phase, of a plurality of phases of an electrical grid, at a sampling rate, wherein the sampling rate is at least equal to a carrier frequency of the radio signal; generate, via the sensor, an electrical signal in response to the electrical property; generate snapshot data based at least in part on the radio signal and the electrical signal; and transmit the snapshot data.

In a further embodiment, the carrier frequency is from about 275 kHz to about 1.75 MHz. In a further embodiment, the radio signal is an injected signal. In a further embodiment, the stored instructions further adapt the at least one processor to: generate a radio signal value in response to the radio signal, wherein the snapshot data includes the radio signal value. In a further embodiment, the snapshot further includes the electrical signal. In a further embodiment, the snapshot is structured to map the radio signal value to the electrical signal. In a further embodiment, the snapshot includes the electrical signal. In a further embodiment, the stored instructions further adapt the at least one processor to: determine an electrical grid event based at least in part on the snapshot; and transmit an indication of the electrical grid event. In a further embodiment, the electrical grid event corresponds to a power outage. In a further embodiment, the electrical grid event corresponds to at least one of: a power level surge; or a power level decrease. In a further embodiment, the electrical grid event corresponds to at least one of: a change in impedance; a change in voltage; or a change in current.

As will be understood, embodiments of the current disclosure have a variety of use cases. For example, one non-limiting use case of synchronizing electrical meter using a radio signal, as disclosed herein, is the localization of power events, e.g., down power lines and/or malfunctioning equipment, e.g., transformers, connection points, distribution stations, etc. Another example use case includes synchronizing grid monitoring devices that may be disposed at locations other than businesses and/or residences, e.g., monitoring devices disposed at a substation and/or along a power line run. Another use case includes detecting if a main line 216 (FIG. 2) to a house has been incorrectly connected/coupled to a different grid phase after an incident, e.g., a storm, from which it was previously connected/coupled prior to the incident. Another use case of the current disclosure include determining a phase offset of a voltage signal for a main line 216 (FIG. 2). As will be understood, detection of a phase offset greater-than 60° may indicate a misconfigured and/or malfunctioning piece of equipment on the electrical grid. Another use case is detecting supraharmonics (SH), e.g., one or more power supplies switching at and/or near the same frequency.

While the disclosure has been disclosed in connection with the preferred embodiments shown and described in detail, various modifications and improvements thereon will become readily apparent to those skilled in the art. Accordingly, the spirit and scope of the present disclosure is not to be limited by the foregoing examples but is to be understood in the broadest sense allowable by law.

What is claimed is:

1. A system comprising:
a radio signal reference circuit structured to interpret a reference radio signal value comprising a description of a radio signal from a transmitter that electrically impinges on an electrical grid, the radio signal having a carrier frequency;
a plurality of electrical meters disposed at distinct locations and each electrically coupled to a phase of a plurality of phases of an electrical grid, each of the plurality of electrical meters comprising a sensor structured to:
interrogate an electrical property of the electrically coupled phase at a sampling rate,
wherein the sampling rate is at least equal to the carrier frequency, and
generate an electrical signal in response to the electrical property;
a time alignment circuit structured to:
determine an expressed radio signal value for each of the plurality of electrical meters by processing the corresponding electrical signal to determine a time alignment metric in response to the reference radio signal value and the expressed radio signal value for each of the plurality of electrical meters, and
determine a time synchronized electrical signal for each of the plurality of electrical meters in response to the time alignment metric; and
a synchronization provisioning circuit structured to transmit the time synchronized electrical signal for each of the plurality of electrical meters.

2. The system of claim 1, wherein the sensor interrogates the electrical property distinctly from an interrogation used to determine the expressed radio signal value.

3. The system of claim 1, wherein the time alignment circuit is further structured to:
determine offsets between the reference radio signal value and the expressed radio signal value for each of the plurality of electrical meters, wherein the time alignment metric is based at least in part on the offsets.

4. The system of claim 3, wherein the time alignment metric is at least one of:
a point-level metric;
a global-meter-level metric;
a bucketed metric; or
based at least in part on a root-mean-square.

5. The system of claim 1, wherein the carrier frequency is from about 275 kHz to about 1.75 MHz.

6. The system of claim 1, wherein the transmitter is an AM transmitter in electrical proximity to the electrical grid.

7. The system of claim 1, wherein the time alignment circuit is structured to process the corresponding electrical signal to determine the expressed radio signal value by at least one of:
filtering the corresponding electrical signal via a band pass filter;
demodulating the corresponding electrical signal; or
filtering the corresponding electrical signal with a low pass filter.

8. The system of claim 1 further comprising:
an event detection circuit structured to determine an electrical grid event based at least in part on the time synchronized electrical signal for each of the plurality of electrical meters; and
a detected event provisioning circuit structured to transmit an indication of the electrical grid event.

9. The system of claim 1, wherein the expressed radio signal value for each of the plurality of electrical meters corresponds to the radio signal from a perspective of the corresponding electrical meter.

10. A method comprising:
interpreting, via a radio signal reference circuit, a reference radio signal value comprising a description of a radio signal from a transmitter that electrically impinges on an electrical grid, the radio signal having a carrier frequency;
for each of a plurality of sensors, interrogating, via the sensor and at a sampling rate, an electrical property of one of a plurality of electrically coupled phases of an electrical grid, wherein:
each of the plurality of sensors forms part of one of a plurality of electrical meters disposed at distinct locations,
each of the plurality of electrical meters is electrically coupled to one of the plurality of phases, and
the sampling rate is at least equal to the carrier frequency;
for each of the plurality of sensors, generating, via the sensor, an electrical signal in response to the electrical property;
determining, via a time alignment circuit, an expressed radio signal value for each of the plurality of electrical meters by processing the corresponding electrical signal to determine a time alignment metric in response to the reference radio signal value and the expressed radio signal value for each of the plurality of electrical meters;
determining, via the time alignment circuit, a time synchronized electrical signal for each of the plurality of electrical meters in response to the time alignment metric; and
transmitting, via a synchronization provisioning circuit, the time synchronized electrical signal.

11. The method of claim 10, wherein interrogating, via the sensor and at a sampling rate, an electrical property of one of a plurality of electrically coupled phases of an electrical grid, is distinct from an interrogation by the sensor used to determine the expressed radio signal value.

12. The method of claim 10 further comprising:
determining, via the time alignment circuit, offsets between the reference radio signal value and the expressed radio signal value for each of the plurality of electrical meters, wherein processing the corresponding electrical signal to determine a time alignment metric is based at least in part on the offsets.

13. The method of claim 12, wherein the time alignment metric is at least one of:
a point-level metric;
a global-meter-level metric;
a bucketed metric; or
based at least in part on a root-mean-square.

14. The method of claim 10, wherein the carrier frequency is from about 275 kHz to about 1.75 MHz.

15. The method of claim 10, wherein the transmitter is an AM transmitter in electrical proximity to the electrical grid.

16. The method of claim 10 further comprising:
injecting the radio signal into an environment encompassing at least a portion of the electrical grid.

17. The method of claim 10, wherein processing, via the time alignment circuit, the corresponding electrical signal to determine the expressed radio signal value comprises at least one of:
filtering the corresponding electrical signal via a band pass filter;
demodulating the corresponding electrical signal; or
filtering the corresponding electrical signal with a low pass filter.

18. The method of claim 10 further comprising:
determining, via an event detection circuit, an electrical grid event based at least in part on the time synchronized electrical signal for each of the plurality of electrical meters; and
transmitting, via a detected event provisioning circuit, an indication of the electrical grid event.

19. The method of claim 18, wherein the electrical grid event corresponds to a power outage.

20. The method of claim 18, wherein the electrical grid event corresponds to at least one of:
a power level surge; or
a power level decrease.

21. The method of claim 18, wherein the electrical grid event corresponds to at least one of:
a change in impedance;
a change in voltage; or
a change in current.

22. The method of claim 10, wherein the expressed radio signal value for each of the plurality of electrical meters corresponds to the radio signal from a perspective of the corresponding electrical meter.
